(19) United States
(12) Patent Application Publication
(10) Pub. No.: US 2025/0155514 A1
(43) Pub. Date: May 15, 2025

(54) METHOD FOR DETERMINING THE AGEING PROGRESSION OF A BATTERY STORAGE DEVICE

(71) Applicant: Siemens Aktiengesellschaft, München (DE)

(72) Inventors: Arno Arzberger, Stegaurach (DE); Michael Kienert, Kaiserslautern (DE); Peter Mas, Chassieu (FR); Ivan Bosmans, Scherpenheuvel-Zichem (BE); Manfred Baldauf, Erlangen (DE); Frank Steinbacher, Eckental (DE)

(21) Appl. No.: 18/838,304

(22) PCT Filed: Feb. 16, 2023
(86) PCT No.: PCT/EP2023/053888

§ 371 Date: Aug. 14, 2024

(30) Foreign Application Priority Data
Feb. 17, 2022 (DE) 10 2022 201 676.9

(51) Int. Cl. G01R 31/392; G01R 31/36; G01R 31/367

(52) U.S. Cl. CPC G01R 31/392; G01R 31/3648; G01R 31/367

(57) ABSTRACT

A method for measuring the ageing of a battery storage device by a High Precision Coulometry method, in which the ageing behaviour of an energy storage device can be determined with little expenditure of time. According to the disclosed, this problem is solved by specifying a sequence of several loading patterns, wherein each loading pattern comprises a plurality of discharging and charging procedures, each with a defined depth of discharge, characteristic average states of charge, current strengths, pause times and/or temperatures, and a) performing the sequence of the plurality of loading patterns, wherein the capacity losses caused by the discharging and charging procedures are measured, and b) determining the residual capacity of the battery storage device, wherein steps a) to b) are repeated until the residual capacity reaches a predetermined limit value.

### CROSS-REFERENCE TO RELATED APPLICATIONS

This application claims priority to PCT Application No. PCT/EP2023/053888, having a filing date of Feb. 16, 2023, which claims priority to DE Application No. 10 2022 201 676.9, having a filing date of Feb. 17, 2022, the entire contents both of which are hereby incorporated by reference.

### FIELD OF TECHNOLOGY

The following relates to a method for determining the ageing progression of a battery storage device.

### BACKGROUND

Lithium-ion rechargeable batteries, also referred to as lithium-ion batteries below, are used as energy stores in mobile and stationary applications on account of their high power and energy density. In order to be able to operate these electrochemical energy stores safely, reliably and for as long as possible without maintenance, knowledge of critical operating states, in particular with respect to the state of charge and with respect to the state of health, that is as accurate as possible is necessary.

It is conventional that the aging of a battery, in particular what is known as the cyclic aging, can be negatively affected by high temperatures and rapid charging at low temperatures, depending on the state of charge, the depth of discharge, and the charging power and the discharge power. It is therefore possible that the same type of battery cell can handle a different large number of load cycles depending on the specified parameters.

In order to determine the expected aging process, an aging characteristic of the battery cell used is determined in the conventional art by measurements during the design phase of a battery system. The real aging rate with real load profiles is often not tested. Rather, the aging rate, or the cycle stability, is determined on compressed load profiles in so-called RAFF tests. These results are used to parameterize empirical aging models which show the aging process in the application. A future aging process determined on the basis of physical and/or chemical measurements depending on the load profile, the operating point and the ambient conditions is difficult to carry out due to the non-linearity of the underlying physical and chemical processes and their complex interactions.

Predicting the state of health of a battery is unfavorably complex. The parameterization of a meaningful aging model is therefore often unfavorably very time-consuming. Furthermore, assumptions often have to be made to assess the aging, which disadvantageously render the assessment inaccurate.

This has the detrimental effect that battery storage units are dimensioned to be larger than the performance and lifetime requirements require, in order to ensure sufficient power and thus to be able to comply with liability and warranty commitments.
According to the conventional art, the aging of electrochemical energy stores, in particular Li-ion batteries, branches into two fundamentally distinguishable branches.
Behind the branch of “cyclic” aging is the observation that Li-ion batteries lose part of their storage capacity for electrical charge with each load cycle. The speed at which the so-called residual capacity decreases depends on the load profile, the operating point and the ambient conditions of the battery.
For the measurement of cyclic aging, a repeated change from checkup tests and the so-called cycling takes place according to the conventional art. During cycling, so-called cycle profiles are periodically applied to the cells under different environmental conditions (e.g., temperature, pressure, etc.). The cycle profiles used may be current profiles or power profiles, less commonly voltage profiles. The typical variables for defining the profiles that are run through periodically during cycling are: current intensity (C-rate), electrical power (CP-rate), mean state of charge (SOC) and/or depth of discharge (DOD).
Behind the branch of “calendar” aging is the observation that Li-ion batteries age even when they are not used (charged and discharged) at all.
Calendar aging is measured according to the conventional art in so-called storage tests. In this case, the cells are stored at different combinations of storage temperature and state of charge (SOC). Storage is effected either with open terminals or, using a potentiostat, at a constant voltage.
In order to determine the aging rate, a so-called checkup test is performed for both branches at regular intervals of time. The so-called residual capacity of the cell, i.e., the maximum amount of charge that can be removed under standard conditions, is measured. The aging rate, e.g., for design purposes, is then calculated from the progression of the results.
The results are also the basis for parameterizing empirical aging models. All the results are approximated to a model therein by a mathematical optimizer.

Proceeding from the conventional art described above/proceeding from the problem described above, embodiments of the invention are based on the aspect of providing a method in which the aging behavior of an energy storage unit can be ascertained with little expenditure of time.

### SUMMARY

An aspect relates to a method for measuring the aging of a battery storage unit by a high-precision coulometry (HPC) method. In this case, a battery storage unit should be understood as meaning, in particular a lithium-ion rechargeable battery or a lithium-ion battery that is exposed, in particular to cyclic and calendar aging, which reduces its maximum usable capacity over the lifetime of the battery storage unit.

In embodiments, the method provides specifying a sequence comprising multiple load patterns. Here, each load pattern comprises a plurality of discharging and charging processes, each with a defined depth of discharge (DOD), characteristic average states of charge (SOC), current intensities, pause times and/or temperatures.

In accordance with the method according to embodiments of the invention, in step a), the sequence of the multiple load patterns is run through, wherein the losses of capacity (dKap) caused by the discharging and charging processes are measured. Furthermore, in step b) of embodiments of the method according to the invention, the residual capacity of the battery storage unit is determined.

The method according to embodiments of the invention makes provision for steps a) to b) to be repeated until the residual capacity, determined in step b), has reached a predetermined limit value.

In an embodiment of the invention, the predetermined limit value, at which the repetition of steps a) and b) is stopped, corresponds to the end of capacity (EOL) of the battery storage unit. In this case, the end of the capacity corresponds, in particular to the capacity from which the battery storage unit is not usable, or is usable only with significant deficiencies, for a predetermined intended use.

In a further embodiment, the predetermined limit value corresponds to a residual capacity of 70% or 80% of the initial capacity, that is to say, the capacity of the battery storage unit after manufacture or, in the case of second life batteries, at the beginning of the measurement process.

Furthermore, the sequence and/or the load patterns can be selected according to embodiments of the invention so that they simulate an intended use of the battery storage unit as realistically as possible. The load patterns can be adjusted to specific usage possibilities for battery storage units. The load patterns can thus be selected so that they simulate the use conditions in an electric car, for example.

In a further embodiment, a checkup test is carried out after a particular number of sequences has been run through in order to determine the residual capacity of the battery storage unit.

It is also possible that a load pattern is a plurality of discharging and charging processes with a low depth of discharge (DOD), in particular less than 5% or else less than 2% of the capacity of the battery storage unit, and/or the charging and/or discharging processes is/are charged at a low current intensity, in particular??? A, such that calendar aging of the battery storage unit is ascertained.

In an advantageous embodiment, a charging and discharging rate is symmetrical. In this case, in a further advantageous embodiment, the C coefficient is less than or equal to 0.1, that is to say the charging time to full charge of the battery storage unit is at least 10 hours.

It is also possible that the load patterns of a sequence are selected so that a mixture of calendar and cyclical aging is measured, or else pure cyclical aging or pure calendar aging is measured.

In a further embodiment, the voltage limits for the discharging and charging processes are adapted after a load pattern or a sequence has been passed through.

In a further embodiment, the residual capacity is estimated by continuous evaluation and extrapolation of the ΔKap value by virtue of the ΔKap value being subtracted from the capacity. As an alternative and/or in addition, the residual capacity can be estimated by a running evaluation of the cycled amount of charge.

The load pattern may also comprise a cycle profile, which is a current profile and/or a power profile.

In an embodiment, asymmetrical and/or symmetrical pauses are inserted after a charging and/or a discharging process.

In a further embodiment, the battery storage unit comprises battery cells and the sequence of HPC measurements and/or the load patterns is/are selected for a respective battery cell type and/or a respective target application.

In embodiments, the method can also be designed so that the measurement of the respective loss of capacity (dKap) is accumulated continuously, and the present state of health is determined for the following measurement.

### BRIEF DESCRIPTION

Some of the embodiments will be described in detail, with references to the following Figures, wherein like designations denote like members, wherein:

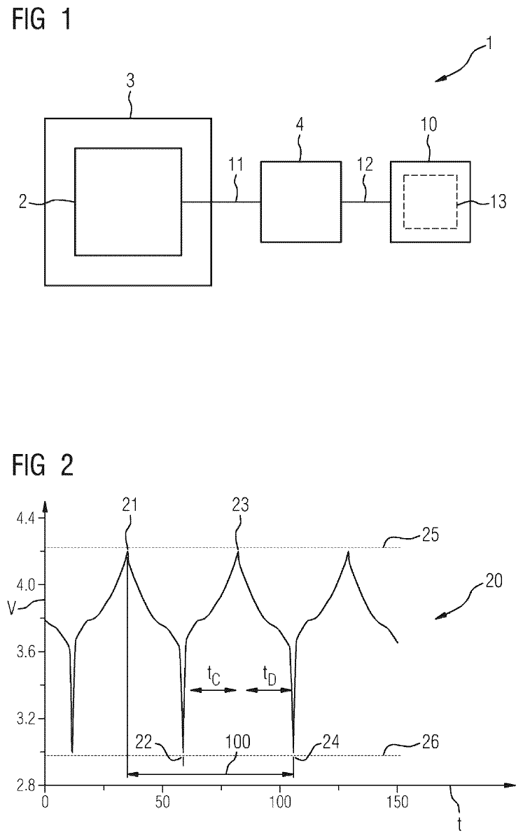

FIG. 1 shows a device for determining the average loss of capacity and a residual capacity using a high-precision colometry device;

FIG. 2 shows a voltage/time graph of a load cycle;

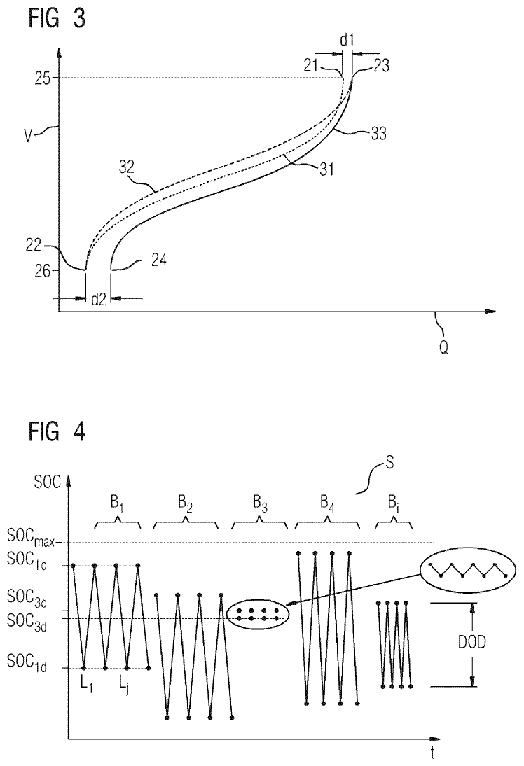

FIG. 3 shows a voltage/charge graph of a load cycle;

FIG. 4 shows a capacity/time graph of an exemplary sequence; and

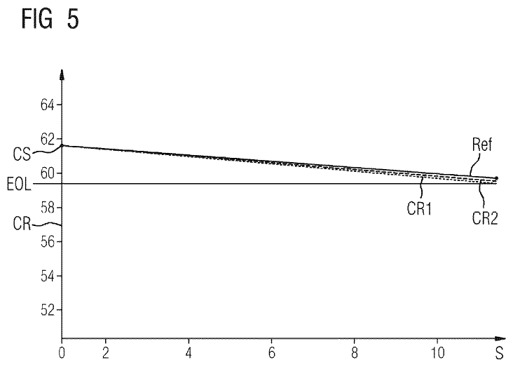

FIG. 5 shows a capacity/cycle number graph.

### DETAILED DESCRIPTION

FIG. 1 shows a device for determining the average loss of capacity and the residual capacity using a high-precision coulometry device 1. The device 1 comprises a battery storage unit 2, wherein the battery storage unit 2 has at least one battery cell. The battery storage unit 2 is arranged in a temperature control chamber 3. The battery storage unit 2 is connected to a high-precision coulometry device 4 via a power cable 11. The high-precision coulometry device 4 is connected in turn to a computing unit 10 via a data cable 12. The high-precision coulometry device 4 records a charge/time graph of the battery storage unit 2 with a great degree of accuracy. In this case, the battery storage unit 2 is charged and discharged cyclically with periodic load cycles 100.

FIG. 2 shows a voltage/time graph plotted by the high-precision coulometry device 4 during a periodic load cycle 100 of the battery storage unit 2. A load cycle 100 comprises discharge from a first state of charge 21 to a second state of charge 22, wherein the first state of charge 21 is at an upper voltage 25 and the second state of charge 22 is at a lower voltage 26. The battery storage unit 2 is subsequently charged in the load cycle 100 from the second state of charge 22 to a third state of charge 23. As the next step in the load cycle 100, the third state of charge 23 is discharged to a fourth state of charge 24. In each individual charging/discharge step, an upper voltage 25 and a lower voltage 26 are retained as voltage limits. The charging lasts for the charging period t_{C}. The discharge lasts for the discharge period to.

Based on the measurement shown in FIG. 2, it is now possible to ascertain, as shown in FIG. 3, what cumulative amount of charge has flown in the individual charging and discharge steps. FIG. 3 shows a graph in which the voltage of the battery storage unit is plotted against the cumulative amount of charge Q. The load cycle 100 begins in turn at the first state of charge 21. The battery storage unit 2 is discharged to the second state of charge 22 in the first discharging process 31. In this case, a first amount of charge Q1 is drawn from the battery storage unit 2. The first amount of charge Q1 can be calculated by equation 1, wherein I denotes the flow of current and to denotes the discharging period:

$$Q 1 = \int I {dt}_{D} \qquad Equation 1$$

The battery storage unit 2 is subsequently charged from the second state of charge 22 to the third state of charge 23 by a first charging process 32 within the load cycle 100. A second amount of charge Q2 is charged into the battery storage unit 2. Q2 can be calculated by equation 2:

$$Q 2 = \int I {dt}_{C} \qquad Equation 2$$

The battery storage unit 2 is subsequently discharged from the third state of charge 23 to the fourth state of charge 24 by a second discharging process 33 within the load cycle 100. The amount of charge Q3 that is drawn can in turn be calculated from the discharging period and the associated flow of current analogously to equation 1.

It is now possible to ascertain a first charge transfer d1 between the first state of charge 21 and the third state of charge 23. A second charge transfer d2 can also be ascertained between the second state of charge 22 and the fourth state of charge 24. A loss of capacity dKap for the load cycle 100 can now be ascertained from the difference between the first charge transfer d1 and the second charge transfer d2 by equation 3.

$$dKap = d 2 - d 1 \qquad Equation 3$$

It is now possible to determine a residual capacity CR based on the average loss of capacity dKap and thus to predict an aging behavior of the battery storage unit being examined for the load profile used under the conditions of the load cycle. The average loss of capacity dKap_{Mittel} is advantageously used to determine the residual capacity. The average loss of capacity dKap_{Mittel} is multiplied by the number of load cycles included in the evaluation and subtracted from the starting capacity CS. This results in the residual capacity CR, as illustrated in equation 4.

$$C R = C S - Z \cdot {dKap}_{Mittel} \qquad Equation 4$$

FIG. 4 shows a schematic illustration of an exemplary sequence S. The sequence S is a load collective of multiple load patterns B₁ to Bᵢ. The order of different load patterns B₁ is shown, wherein the load patterns Bᵢ differ in terms of the respective states of charge SOC and the depth of discharge DODᵢ in the exemplary embodiment. Each load pattern Bᵢ contains a plurality of load cycles Lⱼ, that is to say, charging and discharging processes from an upper state of charge value SOC_{c} to a lower state of charge value SOC_{d}. For reasons of illustration, FIG. 4 illustrates three respective load cycles L for each load pattern B₁₋ᵢ. In practice, the load patterns may comprise significantly more load cycles, for instance 50 to 350 repetitions. It is conceivable that each load pattern B₁₋ᵢ has the same number of load cycles L; however, it is just as conceivable that the different load patterns B₁₋ᵢ have different numbers of load cycles.

In an embodiment, the charge transfers are continuously measured after each load cycle L. However, configurations in which serial testing of the charge transfers takes place after n load cycles, once per load pattern or once per sequence S are conceivable. Based on the measurements of the charge transfers, it is advantageously possible to ascertain the residual capacity of the battery storage unit 2 after the charge transfers have been ascertained.

FIG. 4 schematically illustrates in the load pattern B₃ a test setup for ascertaining the influence of calendar aging. For this, the load cycles are selected so that particularly small depths of discharge are removed. This means that in the load pattern B₃ the charged cycle state of charge SOC_{3c} is only slightly greater than that of the discharged cycle state of charge SOC_{3d}. In this case, the difference between SOC_{3c} and SOC_{3d} is less than 5% of the total maximum state of charge SOCₘₐₓ or, in a further embodiment, less than 2% of the SOCₘₐₓ.

The load cycles with a low depth of discharge DOD are also charged and discharged with low current intensities in order to thus keep the amount of cycle aging low and to increase the amount of calendar aging.

FIG. 5 shows a capacity/cycle number graph of a battery storage unit 2. It shows the profile of the residual capacity CR of the battery storage unit 2 as a function of the sequences S that are run through. The battery storage unit 2 has a starting capacitance CS in sequence 1 that approaches a lower capacity limit EOL over the course of the sequences Si, the lower capacity limit being the end of the capacity, that is to say, the end of the usable functionality of the battery storage unit 2. As soon the residual capacity CR of the battery storage unit 2 falls below the lower capacity limit EOL, the test procedure is ended. Extensive knowledge about the influencing factors on aging are thus obtained for the battery storage unit 2. Therefore, statements can be made for the battery storage unit type of the battery storage unit 2 in relation to which areas of use and ambient conditions these battery storage units are particularly suited to.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

### LIST OF REFERENCE SIGNS

1 Device for predicting the residual capacity
2 Battery storage unit
3 Temperature control chamber
4 High-precision coulometry device
10 Computing unit
11 Power cable
12 Data cable
13 Computer program product
21 First state of charge
22 Second state of charge
23 Third state of charge
24 Fourth state of charge
25 Upper voltage
26 Lower voltage
31 First discharging process
32 First charging process
33 Second discharging process
100 Load cycle
B Load pattern
S Sequence
J Charging cycle number
t Time
tC Charging period
tD Discharging period
V Voltage
Q Charge
CR Residual capacity
CS Starting capacity
d1 First charge transfer
d2 Second charge transfer
dKap Loss of capacity per charging cycle
SOC State of charge
SOCic Charged cycle state of charge
SOCid Discharged cycle state of charge

1. A method for measuring the aging of a battery storage unit by a high-precision coulometry method, comprising:
specifying a sequence of multiple load patterns, wherein each load pattern comprises a plurality of discharging and charging processes, each with a defined depth of discharge, characteristic average states of charge, current intensities, pause times and/or temperatures,
a) running through the sequence of the multiple load patterns, wherein the losses of capacity caused by the discharging and charging processes are measured; and
b) determining the residual capacity of the battery storage unit, wherein steps a) to b) are repeated until the residual capacity has reached a predetermined limit value.

2. The method as claimed in claim 1, wherein the predetermined limit value is the end of capacity of the battery storage unit.

3. The method as claimed in claim 1, wherein the predetermined limit value is a residual capacity of 70% or 80%.

4. The method as claimed in claim 1, wherein the sequence and/or the load pattern is/are selected so that they simulate an intended use of the battery storage unit.

5. The method as claimed in 1, wherein a checkup test is carried out after a particular number of sequences in order to determine the residual capacity of the battery storage unit.

6. The method as claimed in claim 1, wherein a load pattern is a plurality of discharging and charging processes with a low depth of discharge, not greater than 5% of a starting capacity CS of the battery storage unit, and/or is charged and discharged at a current intensity so that the C coefficient is less than or equal to 0.1, such that calendar aging of the battery storage unit is ascertained.

7. The method as claimed in claim 1, wherein a charging and discharging rate is symmetrical.

8. The method as claimed in claim 1, wherein the load patterns of a sequence are selected so that a mixture of calendar and cyclical aging is measured.

9. The method as claimed in claim 1, wherein the voltage limits for the discharging and charging processes are configured after a load pattern or a sequence has been passed through.

10. The method as claimed in claim 1, wherein the residual capacity is estimated by continuous evaluation and extrapolation of the ΔKap value.

11. The method as claimed in claim 1, wherein the residual capacity is estimated by running evaluation of the cycled amount of charge.

12. The method as claimed in claim 1, wherein the load pattern comprises a cycle profile, which is a current profile and/or a power profile.

13. The method as claimed in claim 1, wherein asymmetrical and/or symmetrical pauses are inserted after a charging and/or a discharging process.

14. The method as claimed in claim 1, wherein the battery storage unit comprises battery cells and the sequence of HPC measurements and/or the load patterns is/are selected for a respective battery cell type and/or a respective target application.

15. The method as claimed in claim 1, wherein the measurement of the respective loss of capacity is accumulated continuously and the present state of health is determined for the following measurement.
